(19) United States
(12) Patent Application Publication
(10) Pub. No.: US 2025/0221084 A1
(43) Pub. Date: Jul. 3, 2025

(54) SYSTEMS AND METHODS FOR SOLAR PANEL TRACKING

(71) Applicant: Terabase Energy, Inc., Berkeley, CA (US)

(72) Inventors: Allan Daly, Albany, CA (US); Peter Long Martin, Palo Alto, CA (US); Javid Morteza Alasti, Palo Alto, CA (US); Soren Jensen, Corte Madera, CA (US)

(73) Assignee: Terabase Energy, Inc., Berkeley, CA (US)

(21) Appl. No.: 18/397,300

(22) Filed: Dec. 27, 2023

(51) Int. Cl. H01L 31/02; G06K 7/14; H01L 23/544

(52) U.S. Cl. CPC H10F 77/00; G06K 7/1413; H01L 23/544; H01L 2223/54446

(57) ABSTRACT

Solar panels may have manufacturing defects that warrant a recall by solar panel manufacturers. Given the large quantity of solar panels in a solar farm, it is challenging to identify and track those panels affected by the recall. The present invention describes system and method embodiments for solar panel tracking for the convenience of solar panel service or replacement. Panel identifiers of solar panels in a solar table installed on an installation site of a solar farm are scanned such that the panel identifiers of the solar panels may be associated with the geographical information at the installation site. A geographical database for solar panels may be created and updated, with each panel having an entry of panel information and geographical information. When a recall is issued, involved solar panels in the solar farm may be quickly and accurately identified using the geographical database.

### TECHNICAL FIELD

The present disclosure relates generally to tracking of solar panel. More particularly, the present disclosure relates to systems and methods for solar panel tracking during or after installation for the convenience of solar panel service or replacement.

### BACKGROUND

The importance of solar power systems is well understood by one of skill in the art. Government agencies and companies are scaling the size and number of solar solutions within their energy infrastructure. This transition from traditional fossil fuel energy systems to solar energy solutions presents several challenges. One challenge is cost-effective management and tracking the large quantities of solar panels around the site during and after the construction process.

FIG. 1 shows a typical solar farm 105 comprising an array of installed solar tables 110. Each table comprises multiple solar panels 115. A large-scale solar farm typically includes thousands of solar panels that are located across a multi-acre terrain and that are electrically coupled to provide a source of energy. These large-scale systems are oftentimes located in remote areas and require a significant investment in materials, resources, and labor in their installation and design. The sourcing and delivery of materials and resources for these installations can be problematic and inconsistent. For example, solar panels in a large solar farm may be sourced from multiple manufacturers and delivered in multiple batches. A further complication is the consistent handling and tracking of a large quantity of solar panels during and after the installation processes at each point of installation within the site.

Like any manufactured product, solar panels may have manufacturing defects that warrant a recall by solar panel manufacturers. When a recall is issued, a solar farm may request a return or service for solar panels covered by the recall. Given the large quantity of solar panels in a solar farm, it is challenging to identify and locate those panels affected by the recall.

What is needed are systems and methods for solar panel tracking during or after installation for the convenience of solar panel service or replacement.

### BRIEF DESCRIPTION OF THE DRAWINGS

References will be made to embodiments of the invention, examples of which may be illustrated in the accompanying figures. These figures are intended to be illustrative, not limiting. Although the invention is generally described in the context of these embodiments, it should be understood that the description is not intended to limit the scope of the invention to these particular embodiments. Items in the figures may be not to scale.

FIG. 1 depicts a typical large-scale solar farm comprising an array of installed solar tables, with each solar table comprising multiple solar panels.

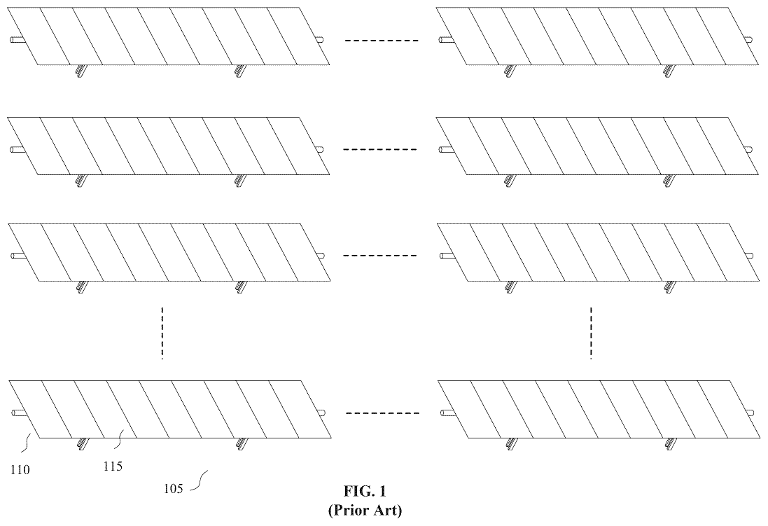

FIG. 2 depicts a prior art assembly and installation process of large-scale solar panel systems.

FIG. 3 depicts a diagram showing a centralized assembly and installation of solar panels using a mobile transport of solar tables in accordance with various embodiments of the invention.

FIG. 4 depicts a perspective view of a solar table in a mobile transport according to various embodiments of the present invention.

FIG. 5 depicts a system diagram for solar panel tracking according to various embodiments of the invention.

FIG. 6 depicts a process for solar panel tracking according to various embodiments of the invention.

FIG. 7 depicts a solar table installed at an installation site for solar panel tracking according to various embodiments of the invention.

FIG. 8 depicts an alternative process for solar panel tracking according to various embodiments of the invention.

FIG. 9 depicts a process for identifying defective solar panels according to various embodiments of the invention.

### DETAILED DESCRIPTION OF EMBODIMENTS

In the following description, for purposes of explanation, specific details are set forth in order to provide an understanding of the invention. It will be apparent, however, to one skilled in the art that the invention can be practiced without these details. Furthermore, one skilled in the art will recognize that embodiments of the present invention, described below, may be implemented in a variety of ways, such as a process, an apparatus, a system, a device, or a method.

Components, or features, shown in diagrams are illustrative of exemplary embodiments of the invention and are meant to avoid obscuring the invention. It shall also be understood that throughout this discussion that components may be described as separate functional units, which may comprise sub-units, but those skilled in the art will recognize that various components, or portions thereof, may be divided into separate components or may be integrated together, including integrated within a single system or component. It should be noted that functions or operations discussed herein may be implemented as components. Components may be implemented in a variety of mechanical structures supporting corresponding functionalities.

Furthermore, connectivity between components or systems within the figures are not intended to be limited to direct connections. Also, components may be integrated together or be discrete prior to the construction.

Reference in the specification to “one embodiment,” “preferred embodiment,” “an embodiment,” or “embodiments” means that a particular feature, structure, characteristic, or function described in connection with the embodiment is included in at least one embodiment of the invention and may be in more than one embodiment. Also, the appearances of the above-noted phrases in various places in the specification are not necessarily all referring to the same embodiment or embodiments.

The use of certain terms in various places in the specification is for illustration and should not be construed as limiting. A component, function, or structure is not limited to a single component, function, or structure; usage of these terms may refer to a grouping of related components, functions, or structures, which may be integrated and/or discrete.

Further, it shall be noted that: (1) certain components or functions may be optional; (2) components or functions may not be limited to the specific description set forth herein; (3) certain components or functions may be assembled/combined differently across embodiments; and (4) certain functions may be performed concurrently or in sequence.

Furthermore, it shall be noted that many embodiments described herein are given in the context of the assembly and installation of large numbers of solar tables within a system, but one skilled in the art shall recognize that the teachings of the present disclosure may apply to other large and complex construction sites in which certain key components may be impacted by potential recall and may be challenging to track accurately.

In this document, “large-scale solar system” refers to a solar system having 1000 or more solar panels. The word “resources” refers to material, parts, components, equipment or any other items used to construct a solar table and/or solar system. The word “personnel” refers to any laborer, worker, designer or individual employed to construct, install, or maintain a solar table or solar system. The term “solar table” refers to a structural assembly comprising a torque tube and/or purlins with module rails. Some types of solar tables may have supplemental structure that allows it to connect to foundations/piles while other types do not have this supplemental structure. A solar table may have (but is not required) one or more solar panels and/or electrical harnesses. The term “solar table mobile transport” (hereinafter, “mobile transport”) describes a vehicle used to move a solar table to an installation site and facilitate an installation process of the solar table. A mobile transport may be driven by personnel, controlled by remote control or move autonomously within at least a portion of a solar system construction site. The term “transport component” refers to a lower portion of the mobile transport that provides movement and includes wheels (or similar features such as a tractor assembly or robotic system), steering mechanism (autonomous or personnel driven) and braking mechanism. The word “pile” refers to a grounded pole, column, or beam that is partially inserted into ground and served as a foundation for subsequent constructions, such as brackets and/or torque tubes of a solar table.

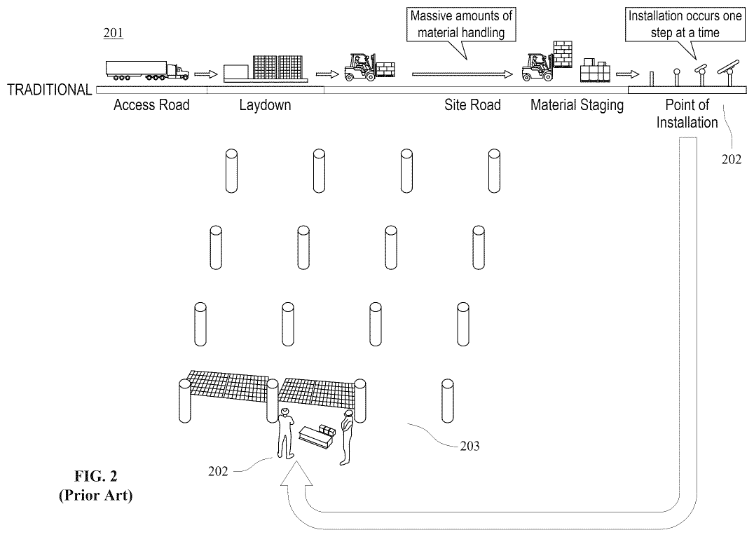

FIG. 2 illustrates a typical prior-art installation process for a large-scale solar farm. This prior-art installation process is implemented such that all mounting equipment for each solar panel is individually assembled and installed at its location within the solar farm. This traditional deployment 201 relies on materials, including solar panels, being delivered to a deployment site via an access road. The materials are then processed and staged at the deployment site by a crew. A small portion of this delivered material is then moved by heavy equipment to a specific location where a solar panel and mounting equipment are assembled and installed at that location 202. The step is then repeated for an adjacent location 203 where materials are subsequently delivered, assembled, and installed for a neighboring solar table within the system. While this approach may be effectively deployed in the installation of smaller solar systems and manageable for solar panel tracking, it becomes cost-prohibitive and challenging for solar panel tracking as the size of the system increases.

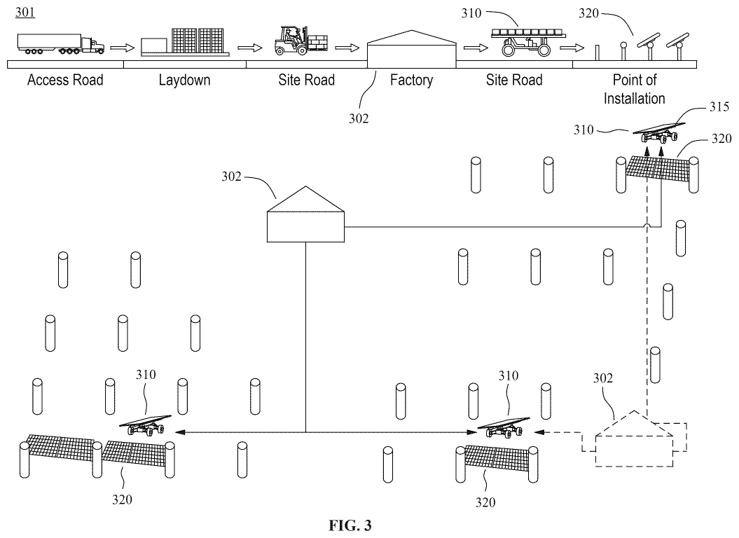

FIG. 3 depicts a diagram showing a centralized assembly and installation of solar panels using a mobile transport of solar tables in accordance with various embodiments of the invention. Embodiments of the invention transition the prior art approach of assembly and installation at single location sites to a centralized and coordinated assembly factory that allows not only a more cost-effective and dynamic process of constructing large-scale solar systems, but also a more accurate way for solar panel tracking and management. This centralized assembly of solar system components, such as solar tables, provides a central location for scanning and identifying individual components like solar panels.

Resources, such as solar panels, are brought to construction site 301 for a large-scale solar farm and initially processed. These resources are delivered to one or more assembly factories 302 where a coordinated and centralized solar table assembly process is performed. In certain embodiments, a construction site may have multiple centralized factories 302. There may be one or more centralized factories 302 strategically located at the site, as shown in FIG. 3. The location and number of centralized factories 302 may depend on several parameters including the size of the site, the terrain of the site, the design of the site and other variables that relate to the construction of the large-scale solar system.

Assembled solar tables and equipment are moved from the factory 302 to a point of installation 320 via motorized vehicles such as a mobile transport 310. In certain embodiments, the mobile transport is specifically designed to transport an assembled solar table 315 along a site road to the point of installation 320. The mobile transport 310 may be driven by personnel, controlled by remote control, or autonomously driven by a computer system. The time and/or sequence in which solar tables are delivered to points of installation 320 may depend on a variety of factors that may be analyzed to configure a preferred schedule.

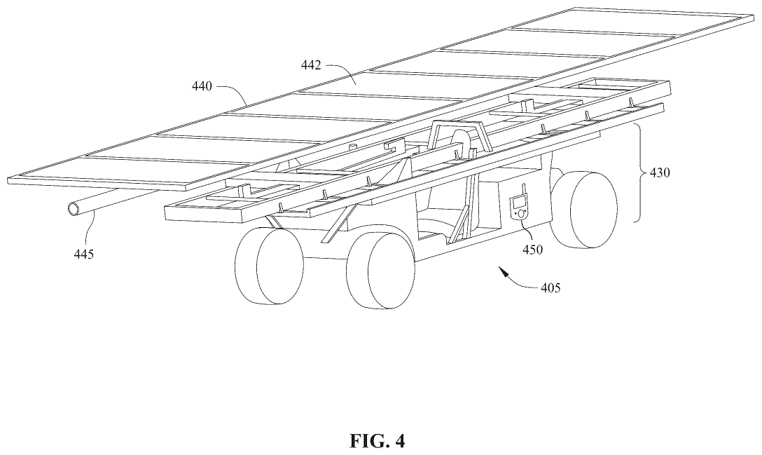

FIG. 4 depicts a perspective view of a solar table in a mobile transport according to various embodiments of the present invention. This mobile transport 405 comprises a transport component 430 that can securely move an assembled solar table 440 to an installation point. The mobile transport 405 may comprise components to allow a dynamic alignment process for a torque tube 445 of the solar table 440 at the installation site. This mobile transport 405 may further comprise a Global Positioning System (GPS) receiver 450 to record a GPS coordinate of the mobile transport 405 at various locations, such as an installation location where the mobile transport 405 arrives to unload the solar table 440 for installation. The GPS receiver 450 may be a built-in GPS receiver or a standalone GPS receiver attached to the mobile transport 405.

The transport component 430 comprises a vehicular segment that can move throughout a solar system construction site under the control of a driving system. Examples of the vehicular segment include a wheel system, tractor system and/or robotic movement system to move a solar table from a factory to an installation point. The transport component 430 comprises a driving system that effectively controls the movement of the mobile transport as it carries a solar table from a centralized factory to an installation site. Examples of a driving system include systems that are controlled by an in-vehicle driver, a remote control being used by personnel or an autonomous driving system. One skilled in the art will recognize that the transport component 430 may be modified and/or supplemented with a variety of structural and functional elements to further assist in the transportation of solar tables within a solar system construction site.

The assembled solar table 440 may comprise one or more solar panels 442 and may be designated for installation at a corresponding installation site in the solar farm. Delivery of an assembled solar table to the installation site may require an alignment process at the installation site. The installation site may be associated with a designated pair of piles to support the solar table, with each pile having predetermined geographic information, such as a GPS coordinate or local geographical information (e.g., a row number and a column number for the pile among all piles within the solar farm). Such predetermined geographic information for each pile may be obtained once the infrastructure works for pile installation and verification are finished. In one or more embodiments, the predetermined geographic information may be saved in a database, e.g., a local or a cloud database, and accessible by authorized personnel.

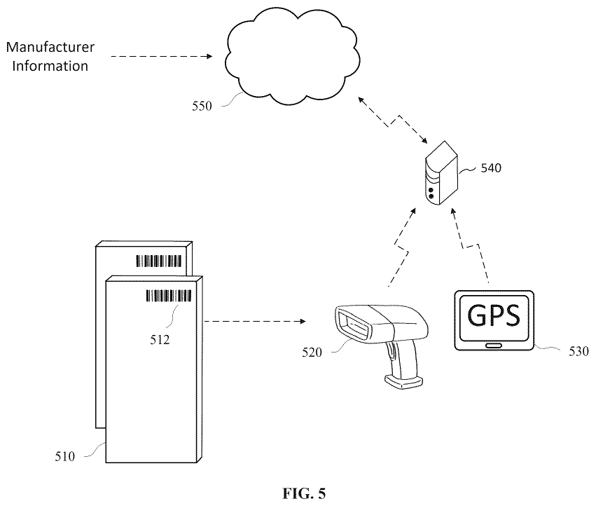

FIG. 5 depicts a system diagram for solar panel tracking according to various embodiments of the invention. Given a plurality of solar panels with each panel 510 having a panel identifier 512, a scanner 520 is used to scan the panel identifier 512 to read solar panel information, such as panel manufacturer, manufacturing data, serial number, etc. A geographical sensor 530, such as a GPS receiver, may record geographical information when the panel identifier 512 is read. The geographical sensor 530 and the scanner 520 may be integrated into a single unit or operated as separate units. The read panel information and the recorded geographical information may be transmitted, directly or indirectly via a mobile computing device, to a computing device 540, e.g., a local server or a cloud server, which may generate a geographical database for the plurality of solar panels, with each solar panel having an entry of panel information and geographical information. The geographical database may be stored locally or in a cloud 550 for authorized access and/or updates. The geographical database may be used to identify and locate specific solar panels based on panel information, such as a serial number or any other panel-specific information that is of interest to the solar farm owner or maintenance crew. The geographical database provides a means to identify and display the location of individual modules in the database in a graphical manner. Panel manufacturers typically issue a recall when actual or potential panel manufacturing defects are found. The recall may include a range of serial numbers for affected solar panels. Such recall information may be entered, automatically or manually, into the geographical database to identify the geographical position of the affected panels. An identification output may be rendered in graphical form in which the geographical position of each affected panel may be translated into a row and a position within that row. For example, the identification output may be a graphical representation of a solar farm with the affected panels highlighted in a color different from unaffected panels.

It shall be noted that during the installation process of the plurality of solar panels, the panel identifier of each panel may be read multiple times using different scanners, with or without geographical information recorded for each reading. For example, during or after assembling multiple solar panels into a solar table, the panel identifiers of the multiple solar panels may be read for the purpose of working flow and inventory management, which may be implemented without the geographical information of the assembling place. While after the solar table is delivered by a mobile transport to an installation site, the panel identifiers of multiple solar panels may be read again using a scanner with geographical information of the installation site recorded. Alternatively, the installation location of a single or multiple solar panel(s) may be obtained by a GPS receiver and associated with the identifiers of individual solar modules.

Physical scanning of the panel identifiers may be done in a centralized assembly location during or after the assembly of the solar table that is transported by the mobile transport 405 to an installation location. Alternatively, the scanning of the panel identifiers can be done at the installation location. The GPS location of the installation location may be provided by a GPS receiver located on the mobile transport 405, or by a separate piece of equipment at the installation location. For example, the GPS receiver located on the mobile transport 405 may record a GPS coordinate where the mobile transport 405 unloads the solar table to complete a table installation and reports the GPS position back to the computing device 540. Given that the computing device 540 already has the information of each individual panel in the solar table, the computing device 540 may assign or associate the GPS coordinate to each individual panels.

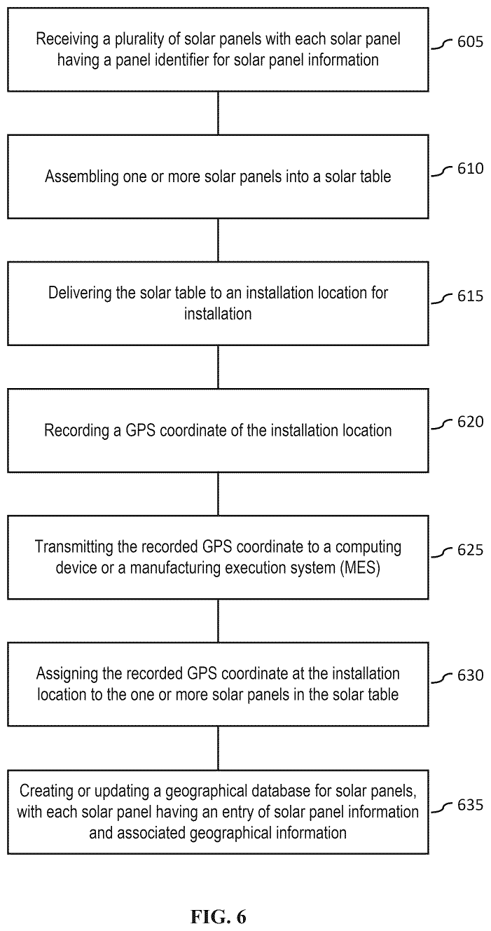

FIG. 6 depicts a process for solar panel tracking according to various embodiments of the invention. In step 605, a plurality of solar panels are received at a centralized assembling factory in a solar farm site. Each solar panel has a panel identifier for solar panel information, such as panel manufacturer, manufacturing data, model number, serial number, etc. The panel identifier may be an identification tag provided by the solar panel manufacturer. Considering that solar panels in a solar farm may be sourced from different manufacturers, the panel identifier may also be created by a solar farm builder (or administrator) for consistency of solar panel identifiers. The panel identifier may be a bar code, a two-dimensional matrix barcode (e.g., a quick response (QR) code), a near-field communication (NFC) tag, etc.

In step 610, one or more solar panels, among the plurality of solar panels, are assembled at the centralized assembling factory into a solar table according to a panel assembling layout. Panel identifiers of the one or more solar panels may be grouped and associated with the solar table in consistence with the panel assembling layout within the solar table. The panel identifiers may be scanned using a first scanner in the centralized assembling factory. Alternatively, the panel identifiers may be scanned at the installation location of the solar table.

In one or more embodiments, a table identifier may be created or used to identify the solar table and be associated with the one or more solar panels in the solar table. As described earlier, the solar table is a structural assembly that may comprise solar panels, a torque tube, and/or purlins with module rails.

In step 615, the solar table is delivered by a mobile transport to an installation location for installation. The installation location may be a predetermined spot between a pair of piles to support the solar table. In one or more embodiments, each pile may have a pile identifier that identifies pile geographic information, e.g., a row number and a column number for the pile among all piles within the solar farm. In another embodiment, the installation location might also be established by a GPS receiver attached to the mobile transport vehicle and associated with the solar table (or the solar panels in the solar panel).

In step 620, a GPS coordinate of the installation location is recorded. The GPS coordinate may be recorded by an onboard GPS receiver on the mobile transport where the mobile transport arrives the installation location to unload the solar table for installation. Alternatively, the GPS coordinate may be recorded by installation personnel using a separate piece of equipment at the installation location.

In step 625, the recorded GPS coordinate is transmitted to the computing device 540 or a manufacturing execution system (MES). In step 630, the recorded GPS coordinate at the installation location is assigned by the computer device 540 to the one or more solar panels in the solar table, considering that the information of the solar panels assembled into the solar table has been available to the computing device 540. In other words, the recorded GPS coordinate is associated with the panel identifiers of the one or more solar panels.

In step 635, a geographical database for solar panels is created or updated with each solar panel having an entry of solar panel information and associated geographical information. The geographical database may be managed or maintained by the computing device 540 and stored locally or in a cloud 550 for authorized access and/or updates.

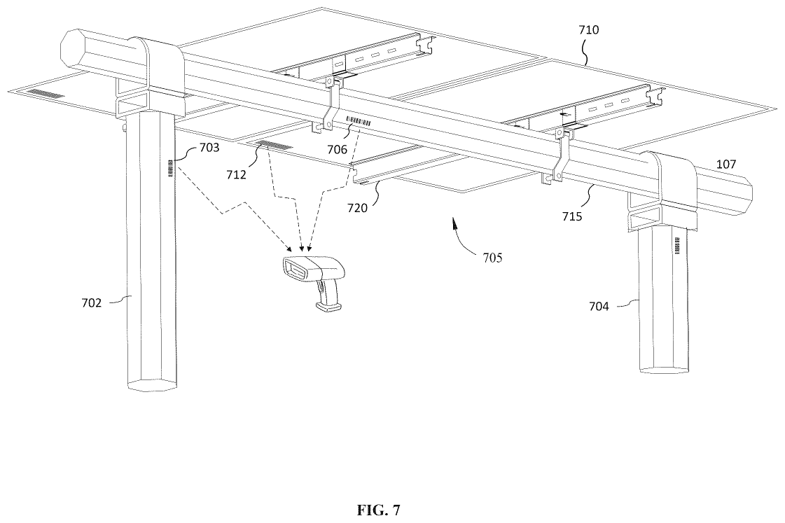

FIG. 7 depicts a solar table installed at an installation site for solar panel tracking according to various embodiments of the invention. As shown in FIG. 7, the solar table 705 is installed between the pile 702 and pile 704. Each pile may have a pile identifier 703 that identifies pile geographic location information. The solar table may have a table identifier 706 that identifies the solar table and a panel assembling layout for the one or more solar panels 710 in the solar table. The solar panel 710 also has a panel identifier 712 for solar panel information.

Upon installation of the solar table, the panel identifiers of the one or more solar panels are associated with the geographical information at the installation site. Such association may be done in various ways, including but not limited to the process described in FIG. 6. For example, the panel identifiers of the one or more solar panels may be scanned or read at the installation site to associate with a GPS coordinate at the installation location or with a pile identifier, which was previously linked to the geographical information at the installation site. Alternatively, the table identifier of the solar table may be read at the installation site to associate a GPS coordinate at the installation location or with a pile identifier. Since the table identifier has been associated with the one or more solar panels in the solar table ready, the association of the table identifier to the geographical information at the installation location also associates the one or more solar panels to the geographical information. The scanning or reading at the installation site may be performed using a portable scanner coupled to a mobile computing device, e.g., a tablet or a laptop, for data uploading.

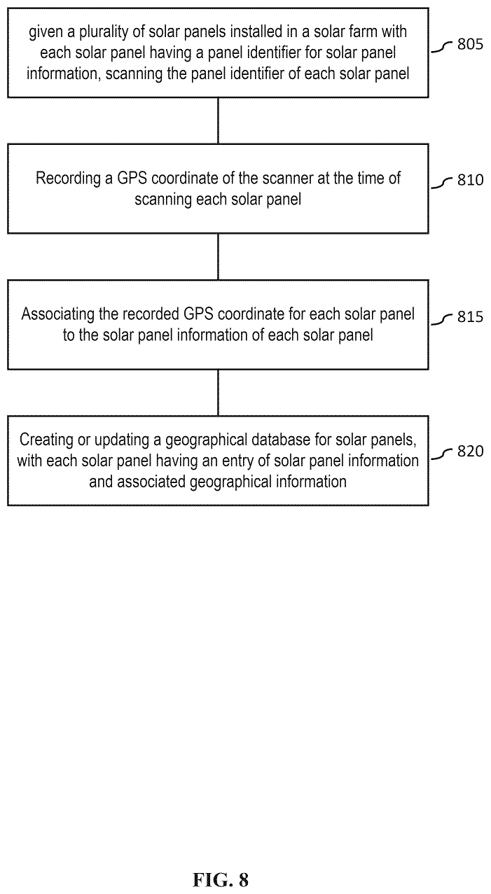

In one or more embodiments, solar panel tracking may be performed manually after installation of solar panels. FIG. 8 depicts such an alternative process for solar panel tracking according to various embodiments of the invention. In step 805, given a plurality of solar panels installed in a solar farm with each solar panel having a panel identifier for solar panel information, a scanner is used to scan the panel identifier of each solar panel. The scanner may be a handheld scanner or a vehicle-mounted scanner that is moved in proximity to each solar panel for scanning.

In step 810, a GPS coordinate of the scanner at the time of scanning each solar panel is recorded. The recording may be done via a GPS receiver that is integrated with the scanner or attached to the scanner. In step 815, the recorded GPS coordinate for each solar panel is associated with the solar panel information of each solar panel. In step 820, a geographical database for solar panels is created or updated with each solar panel having an entry of solar panel information and associated geographical information.

In certain situations, a solar panel manufacturer may issue a recall regarding defective or potentially defective solar panels. The recall may comprise information, such as a range of manufacturing dates, model numbers, and/or serial numbers of solar panels involved. When a recall is issued, a solar farm may request a return or service for solar panels covered by the recall. Given the large quantity of solar panels in a solar farm, it is important to quickly and accurately identify those panels affected by the recall.

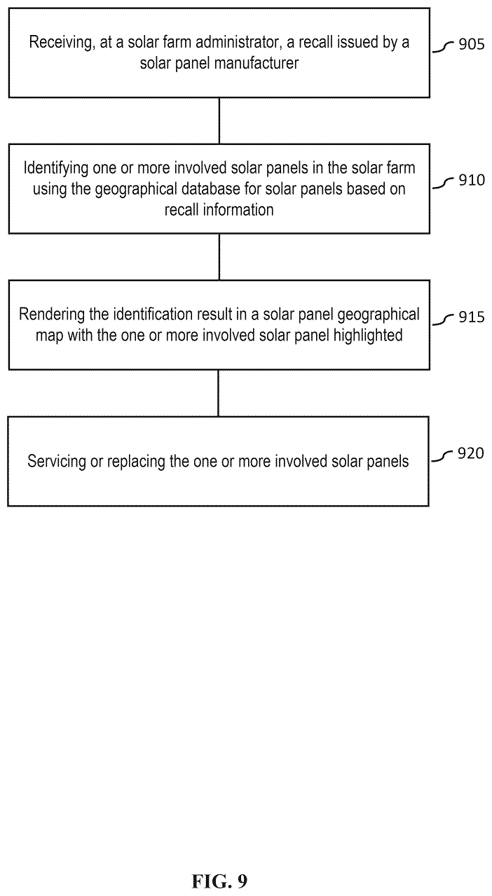

FIG. 9 depicts a process for identifying defective solar panels according to various embodiments of the invention. In step 905, a recall issued by a solar panel manufacturer is received by a solar farm operator or administrator. The recall comprises manufacturing date, model number(s), and/or serial number(s) of solar panels involved by the recall. The recall may also comprise information, such as repair or replacement options for the involved solar panels, measures to handle the involved solar panels, etc.

In step 910, one or more involved solar panels in the solar farm are identified using the geographical database for solar panels based on the recall information. In step 915, the identification result may be rendered in a solar panel geographical map with the one or more involved solar panel highlighted in a color different from solar panels not affected by the recall. In step 920, the involved one or more solar panels are serviced or replaced.

It will be appreciated to those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies, configurations, and combinations.

What is claimed is:

1. A method for solar panel tracking comprising:
receiving a plurality of solar panels with each solar panel having a panel identifier for solar panel information;
assembling, at a centralized assembling factory, one or more solar panels into a solar table according to a panel assembling layout;
delivering, by a mobile transport, the solar table to an installation location in a solar farm for installation;
recording geographical information of the installation location;
assigning the recorded geographical information at the installation location to the one or more solar panels in the solar table; and
creating or updating a geographical database for solar panels, with each of the one or more solar panel having an entry of the solar panel information and associated geographical information.

2. The method of claim 1 wherein the solar panel information comprises one or more of:
panel manufacturer information;
manufacturing time information;
a solar panel model number; and
a solar panel serial number.

3. The method of claim 1 wherein the geographical information of the installation location is a Global Positioning System (GPS) coordinate recorded by a GPS receiver on the mobile transport.

4. The method of claim 1 wherein the geographical information of the installation location is a Global Positioning System (GPS) coordinate recorded by a piece of equipment at the installation location.

5. The method of claim 1 wherein the geographic information of the installation location is a local geographical information comprising a row number and a column number for each pile supporting the solar table at the installation location.

6. The method of claim 1 wherein the geographical database is stored locally or in a cloud for authorized access and/or updates.

7. The method of claim 1 wherein a table identifier is used to identify the solar table and is associated with one or more solar panels.

8. The method of claim 1 wherein the panel identifiers of the one or more solar panels are scanned during or after the assembling of the solar table such that the panel identifiers are grouped and associated to the solar table in consistent with the panel assembling layout.

9. The method of claim 1 further comprising:
upon receiving a recall issued by a solar panel manufacturer, identifying one or more involved solar panels in the solar farm using the geographical database for solar panels based on the recall;
wherein the recall comprises one or more of:
information of manufacturing date;
a model number or model numbers for solar panels covered by the recall; and
a serial number or serial numbers of solar panels covered by the recall.

10. The method of claim 9 wherein an identification result is rendered in a solar panel geographical map with the one or more involved solar panels highlighted.

11. A method for solar panel tracking comprising:
given a plurality of solar panels installed in a solar farm with each solar panel having a panel identifier for solar panel information, scanning, by a scanner, the panel identifier of each solar panel;
recording geographical information of an installation location for each solar panel at a time of scanning each solar panel;
associating the geographical information for each solar panel to the solar panel information of each solar panel; and
creating or updating a geographical database for solar panels, with each of the plurality of solar panels having an entry of solar panel information and associated geographical information.

12. The method of claim 11 wherein the solar panel information comprises one or more of:
panel manufacturer information;
manufacturing time information;
a solar panel model number; and
a solar panel serial number.

13. The method of claim 11 wherein the geographical information of the installation location is a Global Positioning System (GPS) coordinate recorded by a GPS receiver that is integrated with the scanner or attached to the scanner.

14. The method of claim 11 wherein the scanner is a handheld scanner or a vehicle-mounted scanner that is moved in proximity to each solar panel for scanning.

15. A system for solar panel tracking comprising:
a scanner that reads a panel identifier of each of multiple solar panels installed in a solar farm to obtain panel information of each solar panel;
a geographical information receiver to record geographical information of each solar panel;
a computing device coupled to the scanner and the geographical information receiver, the computing device associates the geographical information for each solar panel to the solar panel information of each solar panel; and
a geographical database for the multiple solar panels, each solar panel having an entry of solar panel information and associated geographical information receiver.

16. The system of claim 15 wherein the geographical database is stored locally or in a cloud for authorized access and/or updates.

17. The system of claim 15 wherein the solar panel information comprises one or more of:
panel manufacturer information;
manufacturing time;
a solar panel model number; and
a solar panel serial number.

18. The system of claim 15 wherein the geographical information receiver is a Global Positioning System (GPS) receiver, the geographical information of each solar panel is a GPS coordinate.

19. The system of claim 18 the GPS receiver is integrated with the scanner or attached to the scanner, the GPS coordinate of each solar panel is recorded when the scanner is in proximity to each solar panel for panel identifier scanning.

20. The system of claim 15 wherein the scanner is a handheld scanner or a vehicle-mounted scanner that is moved in proximity to each solar panel for scanning.
